(19) United States
(12) Patent Application Publication
(10) Pub. No.: US 2025/0044733 A1
(43) Pub. Date: Feb. 6, 2025

(54) CIRCUIT BOARD AND IMAGE FORMING APPARATUS

(71) Applicant: CANON KABUSHIKI KAISHA, Tokyo (JP)

(72) Inventor: JUNYA HONDA, Ibaraki (JP)

(21) Appl. No.: 18/790,030

(22) Filed: Jul. 31, 2024

(30) Foreign Application Priority Data
Aug. 3, 2023 (JP) 2023-126985

(51) Int. Cl. G03G 15/00; G03G 21/16; G03G 21/20; H05K 1/02

(52) U.S. Cl. CPC G03G 15/80; G03G 21/1652; G03G 21/20; H05K 1/0206

(57) ABSTRACT

A circuit board includes a first mounting region configured so that a first electronic part is mounted or mountable to the first mounting region, a second mounting region configured so that a second electronic part is mounted or mountable to the second mounting region, and a through via penetrating through the circuit board, wherein the first mounting region includes a first part with an outer edge of the first mounting region and a second part, wherein the second mounting region includes a third part with an outer edge of the second mounting region and a fourth part, wherein, as viewed from a direction perpendicular to a surface on which the first mounting region is provided, the first part and the outer edge of the first mounting region overlap the second mounting region.

### BACKGROUND OF THE INVENTION

### Field of the Invention

The present disclosure relates to a circuit board on which electronic parts are mounted, and to a printer, a copying machine, or a multifunction peripheral, including such a circuit board.

### Description of the Related Art

An image forming apparatus includes a plurality of circuit boards for operating a plurality of constituent parts for use in forming an image. In a typical circuit board, a plurality of electronic parts are implemented and each electronic part is connected by wiring such as a printed wiring line. The electronic parts include, for example, an electronic part for performing a logical operation, an electronic part for performing a drive control, and an electronic part for generating a power supply voltage, and the like. The electronic part achieves a predetermined function either by the single electronic part itself or by cooperating with other electronic parts located in the vicinity.

Japanese Patent Application Laid-open No. 2022-006639 describes a printed wiring board (circuit board) on which electronic parts are mounted. This circuit board has through vias in the board. Through vias improve consistency between a heat transfer pattern on the circuit board and a heat dissipation plate of the electronic part in a case where the electronic part with the heat dissipation plate is mounted, thus heat dissipation of the electronic part is improved.

### SUMMARY OF THE INVENTION

According to one embodiment of the present disclosure, there is provided a circuit board including a first mounting region configured so that a first electronic part is mounted or mountable to the first mounting region, a second mounting region configured so that a second electronic part is mounted or mountable to the second mounting region, and a through via penetrating through the circuit board, wherein the first mounting region includes a first part with an outer edge of the first mounting region and a second part, wherein the second mounting region includes a third part with an outer edge of the second mounting region and a fourth part, wherein, as viewed from a direction perpendicular to a surface on which the first mounting region is provided, the first part and the outer edge of the first mounting region overlap the second mounting region, and the second part of the first mounting region is positioned outside of the second mounting region, wherein, as viewed from the direction, the third part and the outer edge of the second mounting region overlap the first mounting region, and the fourth part of the second mounting region is positioned outside of the first mounting region, and wherein the through via is formed in a region where the first mounting region and the second mounting region overlap.

According to another embodiment of the present disclosure, there is provided a circuit board including a first mounting region configured so that a first electronic part is mounted or mountable to the first mounting region, a second mounting region configured so that a second electronic part is mounted or mountable to the second mounting region, and a through via penetrating through the circuit board, wherein the first mounting region includes a first part with an outer edge of the first mounting region and a second part, wherein the second mounting region includes a third part with an outer edge of the second mounting region and a fourth part, wherein, as viewed from a direction perpendicular to a surface on which the first mounting region is provided, the first part and the outer edge of the first mounting region overlap the second mounting region, and the second part of the first mounting region is positioned outside of the second mounting region, wherein, as viewed from the direction, the third part and the outer edge of the second mounting region overlap the first mounting region, and the fourth part of the second mounting region is positioned outside of the first mounting region, and wherein the through via is formed in a region where the first mounting region and the second mounting region overlap, and a constituent part to be controlled by either one of the first electronic part or the second electronic part.

Further features of the present invention will become apparent from the following description of exemplary embodiments (with reference to the attached drawings).

### BRIEF DESCRIPTION OF THE DRAWINGS

FIG. 1 is a system configuration diagram of an image forming apparatus.

FIG. 2 is a configuration view of the image forming apparatus.

FIG. 3 is a functional block diagram of a circuit board.

FIG. 4 is a circuit diagram of a second voltage generation unit.

FIG. 5 is an explanatory view of a mounting region for an IC on the circuit board.

FIG. 6A and FIG. 6B are exemplary views of a configuration of a circuit board at the time when an IC is mounted.

FIG. 7A and FIG. 7B are exemplary views of a configuration of a circuit board at the time when an IC is mounted.

FIG. 8A, FIG. 8B, and FIG. 8C are exemplary views of a configuration of a circuit board at the time when an IC is mounted.

FIG. 9A, FIG. 9B, and FIG. 9C are exemplary views of a configuration of a circuit board at the time when an IC is mounted.

### DESCRIPTION OF THE EMBODIMENTS

Now, a description of at least one exemplary embodiment of the present disclosure with reference to the accompanying drawings is given.

### <Configuration of Image Forming Apparatus>

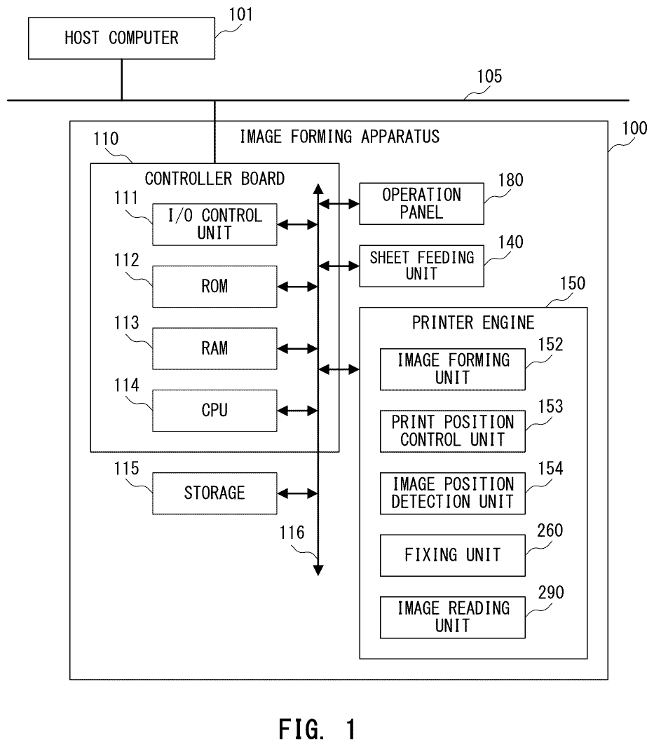

FIG. 1 is a system configuration diagram of an image forming apparatus including a circuit board according to at least one embodiment of the present disclosure. It should be understood that, unless otherwise described, an image forming apparatus 100 may be a system including a plurality of apparatus connected to each other via a network, as long as functions of the image forming apparatus 100 can be implemented.

The image forming apparatus 100 according to the present embodiment is connected to a host computer 101 via a network 105 so that communication is allowed therebetween. The network 105 includes a communication line such as a local area network (LAN), a wide area network (WAN), and a public communication line. A plurality of image forming apparatus 100 and a plurality of host computers 101 may be connected to the network 105. The host computer 101 generates a print job based on input information from a user acquired from an input device (not shown), and transmits the generated print job to the image forming apparatus 100 via the network 105.

The image forming apparatus 100 includes a controller board 110, a storage 115, a sheet feeding unit 140, a printer engine 150, and an operation panel 180. The controller board 110, the storage 115, the sheet feeding unit 140, the printer engine 150, and the operation panel 180 are connected to each other via a system bus 116 so that mutual communication is allowed therebetween.

The controller board 110 includes an I/O control unit 111, a read only memory (ROM) 112, a random access memory (RAM) 113, and a central processing unit (CPU) 114. The I/O control unit 111, the ROM 112, the RAM 113, and the CPU 114 are electronic parts mounted on a circuit board. The controller board 110 functions as a main control unit of the image forming apparatus 100, performs various data processing, and controls the operation of the entire image forming apparatus 100. The circuit board is, for example, a printed wiring board having printed wiring formed thereon.

The I/O control unit 111 controls communication to/from an external apparatus such as the host computer 101 via the network 105.

The CPU 114 executes a computer program stored in the ROM 112 or the storage 115 to control an operation such as image forming processing to be performed by the image forming apparatus 100. The RAM 113 provides a work area used in a case where the CPU 114 executes processing, and performs storage of temporal data or the like. The storage 115 stores large-capacity data, such as image data or print data, on a temporary or long-term basis. For example, the storage 115 stores image data for generating an image for adjustment (e.g., an image for adjustment for use in adjusting an image position) for use in adjusting an image forming condition. The storage 115 is a large-capacity storage device, such as a hard disk drive (HDD) or a solid state drive (SSD). Computer programs, such as a startup program, a control program, and an operation system, to be executed by the CPU 114 are stored in the ROM 112 and the storage 115.

The operation panel 180 is a user interface including an input interface and an output interface. The input interface is, for example, key buttons and a touch panel. The output interface is a display, a speaker, and the like. The operation panel 180 receives an instruction or the like through the operation of the user and inputs the received instruction or the like to the CPU 114. The CPU 114 controls the operation of the image forming apparatus 100 in accordance with the instruction. Further, the operation panel 180 displays a state of the image forming apparatus 100 and various setting screens in accordance with the instruction from the CPU 114.

The sheet feeding unit 140 includes a sheet feeding device including one or more sheet feeding stages, and an entire conveying unit for conveying a sheet from one of the sheet feeding stages to a sheet discharging unit. Each sheet feeding cassette may accommodate the sheet of the same type, however, it may accommodate different types of the sheet. The sheet feeding unit 140 feeds sheets one by one from the sheet feeding stage in accordance with the instruction from the CPU 114.

The printer engine 150 includes an image forming unit 152, a print position control unit 153, an image position detection unit 154, a fixing unit 260, and an image reading unit 290. The image forming unit 152 forms an image (toner image) on the sheet fed by the sheet feeding unit 140. The fixing unit 260 fixes the image (toner image) to the sheet. The image reading unit 290 is arranged downstream of the fixing unit 260 in a conveyance direction of the sheet, and reads the image for adjustment printed on the sheet. The image position detection unit 154 detects an image position on the sheet based on results of reading the image for adjustment by the image reading unit 290. The print position control unit 153 controls the position of the image to be printed on the sheet based on the image position detected by the image position detection unit 154.

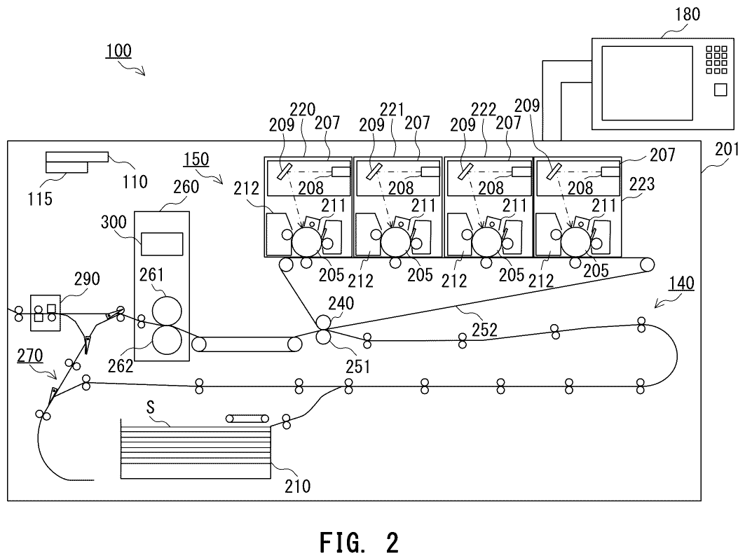

FIG. 2 is a configuration view of the image forming apparatus 100. The image forming apparatus 100 includes the operation panel 180 above a casing 201. Inside of the casing 201, the controller board 110, the storage 115, the sheet feeding unit 140, and the printer engine 150 illustrated in FIG. 1 are provided. The printer engine 150 includes mechanisms forming an engine unit, and an engine control unit for performing control of processing to be performed by each mechanism. The mechanisms forming the engine unit include an optical processing mechanism and a fixing processing mechanism. The optical processing mechanism is used for forming an electrostatic latent image, visualizing the electrostatic latent image, and transferring the visualized image onto a sheet S. The fixing processing mechanism fixes the toner image transferred onto the sheet S.

The image forming unit 152 of the printer engine 150 corresponds to the optical processing mechanism, and includes a Y station 220, an M station 221, a C station 222, a K station 223, an intermediate transfer belt 252, and a secondary transfer outer roller 251. The Y station 220, the M station 221, the C station 222, and the K station 223 have the same configuration, and only differ in colors of images to be formed. The Y station 220 forms a yellow image. The M station 221 forms a magenta image. The C station 222 forms a cyan image. The K station 223 forms a black image. The configuration of the Y station 220 is described here, and description of the configuration of the M station 221, the C station 222, and the K station 223 is omitted.

The Y station 220 includes a photosensitive drum 205, a charging device 211, an exposing device 207, and a developing device 212. The photosensitive drum 205 is a drum-shaped photosensitive member having a photosensitive layer on its surface. The charging device 211 uniformly charges the surface of the photosensitive drum 205 that rotates about a drum shaft. The exposing device 207 scans the charged surface of the photosensitive drum 205 with laser light modulated in accordance with the image data.

The exposing device 207 includes a laser driver, a rotary polygon mirror 208, and a reflecting mirror 209. The laser driver controls light emission of a semiconductor laser (not shown) in accordance with the image data acquired from a printer controller 203 (CPU 114). The laser light emitted from the semiconductor laser moves in a main scanning direction in accordance with the rotation of the rotary polygon mirror 208, and is guided by the reflecting mirror 209 to the surface of the photosensitive drum 205. Thus, the laser beam scans the surface of the photosensitive drum 205 in a drum axis direction. The surface of the photosensitive drum 205 is exposed with light so that an electrostatic latent image is formed thereon.

The developing device 212 visualizes the electrostatic latent image with toner of a corresponding color to form a toner image on the surface of the photosensitive drum 205. A yellow toner image is formed on the photosensitive drum 205 of the Y station 220. A magenta toner image is formed on the photosensitive drum 205 of the M station 221. A cyan toner image is formed on the photosensitive drum 205 of the C station 222. A black toner image is formed on the photosensitive drum 205 of the K station 223.

The intermediate transfer belt 252 is looped around rollers such as a secondary transfer inner roller 240, and rotates in the clockwise direction of FIG. 2. The toner images of the respective colors formed on the respective photosensitive drums 205 are transferred in a superimposing manner onto the rotating intermediate transfer belt 252. The toner image is transferred from the photosensitive drum 205 onto the intermediate transfer belt 252 by applying a bias voltage having a polarity reverse to that of the toner image to the intermediate transfer belt 252. In this manner, the intermediate transfer belt 252 bears a full-color toner image. The intermediate transfer belt 252 rotates to convey the borne toner image to a secondary transfer portion formed of the secondary transfer inner roller 240 and the secondary transfer outer roller 251.

The sheet feeding unit 140 corresponds to a feeding mechanism for the sheet S, and includes a storage unit 210k, which is a sheet feeding cassette for storing the sheet S, conveyance paths, and conveying rollers. The sheet feeding unit 140 conveys the sheet S from the storage unit 210 one by one to the secondary transfer portion. The secondary transfer portion nips and conveys the intermediate transfer belt 252 and the sheet S by the secondary transfer inner roller 240 and the secondary transfer outer roller 251. At this time, a bias voltage having a polarity reverse to that of the toner image is applied to the secondary transfer outer roller 251 so that the toner image is transferred from the intermediate transfer belt 252 onto the sheet S.

The sheet S having the toner image transferred thereon is conveyed to the fixing unit 260 corresponding to the fixing processing mechanism. The fixing unit 260 includes a fixing roller 261, a pressure roller 262, and a circuit board 300. The fixing roller 261 incorporates a heat source. The pressure roller 262 is urged to the fixing roller 261 side. The circuit board 300 controls the fixing processing to be performed by the fixing unit 260. The fixing unit 260 nips and conveys the sheet S having the toner image transferred thereon by the fixing roller 261 and the pressure roller 262 so that the toner image is fixed to the sheet S. At this time, the fixing roller 261 heats and melts the toner image, and presses the sheet S between the fixing roller 261 and the pressure roller 262.

In the manner described above, the image is printed on the sheet S. In a case of duplex printing, the sheet S having the image printed on its first surface (front surface) is re-conveyed to the secondary transfer portion via a reverse path 270. Through conveyance to the secondary transfer portion via the reverse path 270, an image forming surface of the sheet S is reversed. On the sheet S whose image forming surface has been reversed, an image is printed on a second surface (back surface) different from the first surface by the secondary transfer portion and the fixing unit 260.

The sheet S having the image printed thereon passes through the image reading unit 290 so as to be discharged to the outside of the image forming apparatus 100. In a case where the image formed on the sheet S is the image for adjustment for adjusting the image forming condition, the image reading unit 290 is used for reading this image for adjustment.

### <Circuit Board>

In order to perform the image forming processing as described above, the image forming apparatus 100 incorporates various actuators, such as motors and sensors. The actuators are each connected to a circuit board having electronic parts for control mounted thereon. Each electronic part implemented to the circuit board is connected by wiring such as printed wiring. The actuators are controlled at optimum timing by a CPU or other electronic parts for control mounted on the circuit board. A large number of circuit boards are thus provided in the image forming apparatus 100 so as to correspond to the actuators. One or more actuators are controlled by one circuit board.

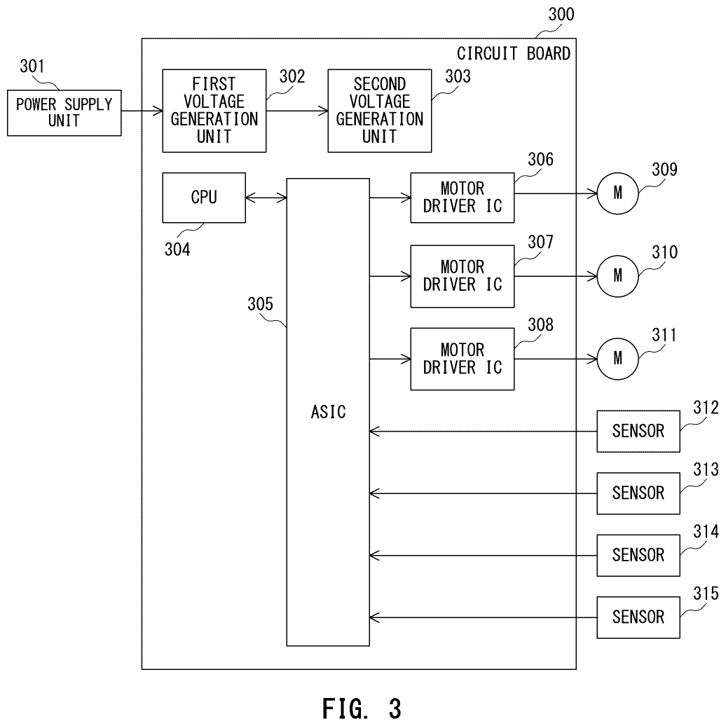

FIG. 3 is a functional block diagram of the circuit board 300 provided in the fixing unit 260. A plurality of motors 309 to 311 in the fixing unit 260 and a plurality of sensors 312 to 315 in the fixing unit 260 are electrically connected to the circuit board 300. The motor 309 is a drive source for driving the fixing roller 261 being a rotary member. The motor 310 is a drive source for urging the pressure roller 262 to the fixing roller 261 side. The motor 311 is a drive source for driving a roller being a rotary member for conveying the sheet S that has been subjected to the fixing processing to the downstream. The sensor 312 is a detector for detecting the sheet S that has been conveyed to the fixing unit 260. The sensor 313 is a temperature detector for detecting the temperature of the fixing roller 261. The sensor 314 is a detector for detecting the sheet S that has been subjected to the fixing processing. The sensor 315 is a detector for detecting the rotation of the fixing roller 261.

A large number of electronic parts are mounted on the circuit board. In the example of FIG. 3, the circuit board 300 includes a first voltage generation unit 302 and a second voltage generation unit 303. The first voltage generation unit 302 is used for generating a predetermined DC voltage from an AC voltage. The second voltage generation unit 303 converts a voltage value of the DC voltage. The circuit board 300 further includes a CPU 304, an application specific integrated circuit (ASIC) 305, and motor driver ICs 306 to 308, which are used for control of the actuators. On the circuit board 300, the following plurality of semiconductor devices (hereinafter referred to as “ICs”) and surrounding electronic parts corresponding to the respective ICs as described are mounted as electronic parts. Each electronic part is electrically connected by wiring of a circuit pattern and the like.

The first voltage generation unit 302 is an AC-DC converter which generates, from an AC power supplied from a power supply unit 301, a supply voltage which is a DC voltage having a predetermined voltage value. The first voltage generation unit 302 of the present disclosure generates a DC voltage of 12 V from an AC voltage of 24 V. The first voltage generation unit 302 supplies the generated DC supply voltage to the second voltage generation unit 303. The second voltage generation unit 303 is a DC-DC converter which generates a DC power supply voltage, from the power supply voltage supplied from the first voltage generation unit 302, having a voltage value different from the power supply voltage. The second voltage generation unit 303 of the present disclosure generates a DC voltage of 5 V from a DC voltage of 12 V. The supply voltage generated by the second voltage generation unit 303 is supplied to the CPU 304 and the ASIC 305. The CPU 304 and the ASIC 305 operate with the power supply voltage supplied from the second voltage generation unit 303. Here, the power supply voltage output from the first voltage generation unit 302 is supplied to the electronic part and motors 309-311 which operate with a voltage value different from the voltage value for operating the CPU 304 or ASIC 305.

The CPU 304 is connected to each of the motor driver ICs 306 to 308 and each of the sensors 312 to 315 via the ASIC 305. The motor driver IC 306 is connected to the motor 309. The motor driver IC 307 is connected to the motor 310. The motor driver IC 308 is connected to the motor 311. The CPU 304 acquires detection results obtained by the sensors 312 to 315 to detect the state of the fixing unit 260 from these detection results. The CPU 304 controls each of the motor driver ICs 306 to 308 via the ASIC 305 in accordance with the detected state of the fixing unit 260, to thereby control the drive of each of the motors 309 to 311. As described above, the CPU 304 and the ASIC 305 control the operation of the fixing unit 260.

The circuit board 300 is provided in the fixing unit 260 and thus controls the operation of the fixing unit 260, but other circuit boards provided in the image forming apparatus 100 similarly control operations of corresponding constituent parts. Each of the circuit boards in the image forming apparatus 100 (including the circuit board 300 and other circuit boards) is connected to the controller board 110 so that communication is allowed therebetween. Communication is allowed between circuit boards via the controller board 110. The circuit boards appropriately control the constituent parts in the image forming apparatus 100 while mutually sharing information on the detection results obtained by the sensors and the control states of the motors.

As described above, a large number of electronic parts are mounted on the circuit board. However, for various reasons such as distribution, environment, and accidents, there is a possibility that a situation in which it becomes difficult to procure at least a part of the large number of electronic parts occurs. For example, recently, it is difficult to obtain ICs due to supply shortages. In order to cope with the situation in which there is an electronic part that is difficult to procure, there is known a method of making research in advance for an electronic part, which is a replacement product, having the same or similar shape and specification as a genuine electronic part. In a case where a problem occurs in part procurement for a genuine product, the replacement product may be procured and mounted on the circuit board so that the manufacture of the circuit board is continued.

However, when selecting a replacement product for an electronic part such as a DC-DC converter, the size and the terminal arrangement of the replacement product differ from that of the genuine product, depending on the manufacturer and specifications. Therefore, it is difficult to use the same wiring pattern on a circuit board for both the genuine product and the replacement product. It is possible to prepare separate circuit boards with different wiring patterns and use different circuit boards for the genuine product and the replacement product. However, in this case, the cost for inspecting, managing, and manufacturing of circuit boards increases, and confusion in the manufacturing process may occur.

Therefore, it is preferable to provide wiring patterns for both the genuine product and the replacement product on a single circuit board, and when one of the genuine product and the replacement product is mounted, the other part is unmounted. In other words, the genuine product and the replacement product are mounted exclusively.

A through via is provided in a circuit board for mounting of an electronic part, and the improving heat dissipation. In a case where a mounting region of the genuine product and a mounting region of the replacement product overlap in the same area, in the center of a mounting region of a heat dissipation plate of one electronic part, the through via to be used during mounting of the other electronic part may be provided. In this case, solder paste melted during mounting of one electronic part may flow into the opposite side of the mounting surface, through the through via to be used during mounting of the other electronic part. This results in insufficient amount of solder between the heat dissipation plate and the mounting surface of the circuit board, which reduces the heat dissipation of the electronic part and lowers the yield rate of the circuit board.

Such a reduction in the heat dissipation can be suppressed by separating the mounting region of the genuine product from the mounting region of the replacement product by a predetermined distance or more. However, as the distance increases, the size of the circuit board also increases. In present disclosure, by suppressing the increase in size and the decrease in the heat dissipation of the electronic part, the decrease in yield rate of circuit board is suppressed. Hereinafter, a specific circuit diagram and a configuration of the circuit board will be explained.

### <Second Voltage Generation Unit>

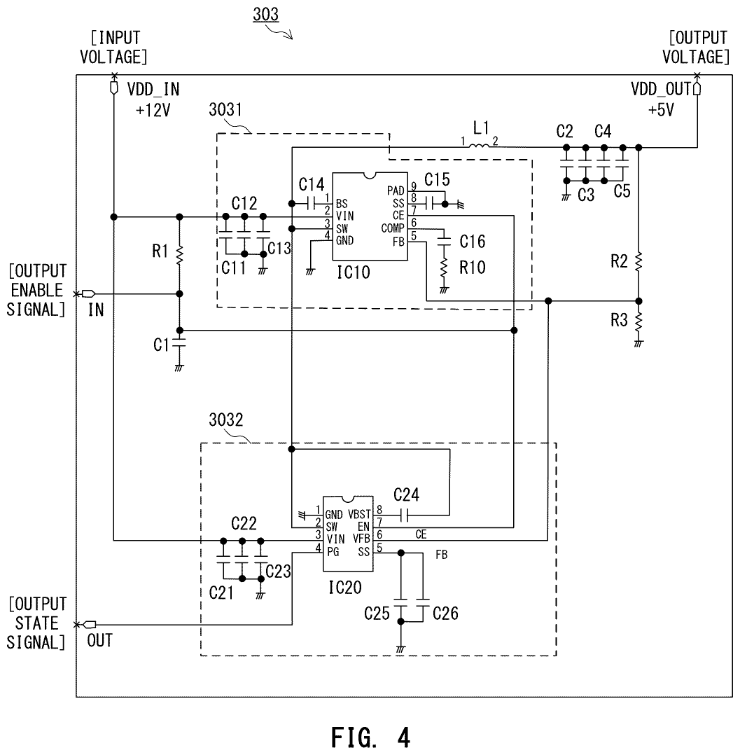

FIG. 4 is a circuit diagram of a second voltage generation unit 303. As described above, the second voltage generation unit 303 is a DC-DC converter. The second voltage generation unit 303 is supplied with a DC voltage of 12 V, which is an input voltage, from a VDD_IN terminal (input terminal), and outputs a DC voltage of 5 V, which is an output voltage, from a VDD_OUT terminal (output terminal). The second voltage generation unit 303 includes an electronic part component in which two or more electronic parts are combined to achieve a predetermined function (in this embodiment, DC-DC conversion function). In the present embodiment, the second voltage generation unit 303 exclusively includes a first electronic part component 3031 and a second electronic part component 3032.

The first electronic part component 3031 and the second electronic part component 3032 are exclusively mounted on the circuit board of the second voltage generation unit 303, according to an electronic part that can be procured. Both the first electronic part component 3031 and the second electronic part component 3032 convert a DC input voltage of 12 V to a DC output voltage of 5 V. For example, the first electronic part component 3031 is a genuine product, and the second electronic part component 3032 is a replacement electronic part.

The first electronic part component 3031 includes an IC 10, which is a DC-DC converter, and a resistor R10 and capacitors C11 to C16, which are unique electronic parts necessary for the operation of the IC 10. The second electronic part component 3032 includes an IC 20, which is a DC-DC converter, and capacitors C21 to C26, which are unique electronic parts necessary for the operation of the IC 20. The second voltage generation unit 303 includes resistors R1 to R3, capacitors C1 to C5, and an inductor L1 as common electronic parts required when either the first electronic part component 3031 or the second electronic part component 3032 is mounted.

The input voltage input from the VDD_IN terminal is supplied to a VIN terminal of the IC 10 of the first electronic part component 3031, or the VIN terminal of the IC 20 of the second electronic part component 3032. The output voltage output from the VDD_OUT terminal is generated at the first electronic part component 3031, or the second electronic part component 3032. The output voltage is output from an SW terminal of the IC 10 of the first electronic part component 3031, or the SW terminal of the IC 20 of the second electronic part component 3032.

An output enable signal input from the VDD_IN terminal is input to a CE terminal of the IC 10 of the first electronic part component 3031, or an EN terminal of the IC 20 of the second electronic part component 3032. The output enable signal can be input to both the IC 10 of the first electronic part component 3031 and the IC 20 of the second electronic part component 3032, and is connected to the connection point between the resistor R1 and the capacitor C1, which are the common electronic parts. The output enable signal is a signal that permits the IC 10 and the IC 20 to output the output voltages. An output status signal output from an OUT terminal is an output signal specific to the IC 20 of the second electronic part component 3032, and is output from the PG terminal of the IC 20. The output state signal is a signal which represents that the IC 20 is outputting the output voltage normally.

In a case where the second electronic part component 3032 is mounted, the output voltage output from the SW terminal of the IC 20 is divided by the resistors R2 and R3 via the inductor L1. This divided voltage is input into a VFB terminal of the IC 20. The IC 20 can determine whether the output voltage has a normal voltage value or not by determining whether a voltage value of the divided voltage is within a target voltage range or not. In a case where the divided voltage is within the target voltage range, the IC 20 determines that the output voltage is normal, and outputs an output state signal (for example, high voltage) indicating that the output voltage is normal. In a case where the divided voltage is not within the target voltage range, the IC 20 determines that the output voltage is abnormal, and outputs an output state signal (for example, low voltage) indicating that the output voltage is abnormal.

In addition, the IC 10 of the first electronic part component 3031 does not have a function to output the output state signal. In a case where the first electronic part component 3031 is mounted, the divided voltage, which is obtained by dividing the output voltage output from the SW terminal of the IC 10 using the resistors R2 and R3, is input to an FB terminal of the IC 10. However, the IC 10 does not have a function to determine whether the output voltage is being output normally or not. Therefore, in a case where the first electronic part component 3031 is mounted, the output state signal is not output from the OUT terminal.

The resistor R10 and the capacitor C16 of the first electronic part component 3031 are unique components of the first electronic part component 3031 since they are dedicated electronic parts required for the IC 10. The capacitors C11 to C15 of the first electronic part component 3031 and the capacitors C21 to C26 of the second electronic part component 3032 have similar connection configurations for the IC 10 and the IC 20, respectively. However, the capacitors C11 to C15 have the characteristic for maintaining the optimal operating performance of the IC 10, and capacitors C21 to C26 have the characteristic for maintaining the optimal operating performance of the IC 20. Thus, the capacitors C11 to C15 are the unique electronic parts of the first electronic part component 3031, and the capacitors C21 to C26 are the unique electronic parts of the second electronic part component 3032.

The inductor L1 and the capacitors C2 to C5, which are the common electronic parts, are electronic parts arranged in a wiring path from the IC 10 and the IC 20 to the VDD_OUT terminal, which is the output terminal of the circuit board. The capacitors C2 to C5 are capacitors for smoothing output voltage. The capacitors C2 to C5, together with the inductor L1, suppress an AC component of the output voltage. The inductor L1 and the capacitors C2 to C5 are electronic parts that are large in size among common electronic parts. As to a circuit board in which the first electronic part component 3031 and the second electronic part component 3032 are mounted exclusively, it is advantageous to treat the larger electronic parts as common electronic parts as much as possible to reduce the size of the circuit board.

The resistors R2 and R3, which are the common electronic parts, are voltage divider resistance to divide the output voltage, as described above. The divided voltage is input to the FB terminal, which is a feedback terminal of the IC 10, or the VFB terminal, which is a feedback terminal of the IC 20. In a case where the divided voltage is lower than the target voltage, both the IC 10 and the IC 20 internally short the SW terminal and the VIN terminal. In a case where the divided voltage is higher than the target voltage, both the IC 10 and the IC 20 internally short the SW terminal and a GND terminal. Therefore, the divided voltage serves as a control signal to control the output voltage. Thus, the resistors R2 and R3 are common electronic parts required by the first electronic part component 3031 and the second electronic part component 3032.

### <Configuration of Connection Land>

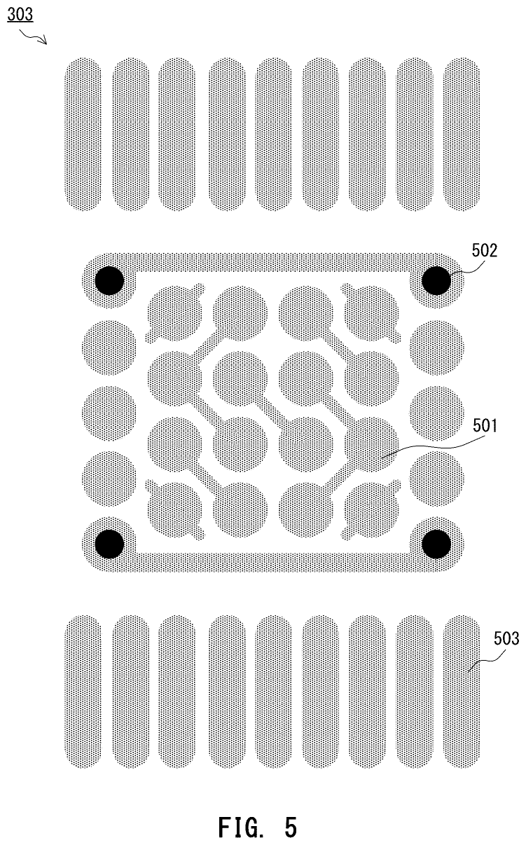

FIG. 5 is an explanatory view of a mounting region for an IC on the circuit board. In the mounting region for the IC, a plurality of connection lands 501 to which the IC is connected, and a land for lead 503 to which a lead of the IC is connected are provided. The through vias 502 is formed in the connection land 501. In a case where the IC is mounted, the IC is soldered on the connection land 501 and the land for lead 503 for lead.

A center portion of the connection land 501 is formed so that, in order to prevent solder from leaking from the connection land in a case where the IC is mounted, each connection land 501 has the same area and the same shape (circular shape in this case). The through vias 502 are formed at four corners of an outer edge of the connection land 501 in order to prevent solder balls from being generated in a case where the IC is mounted. The through vias 502 may be formed at positions other than the four corners. In a case where the IC is mounted, the heat dissipation plate of the IC is caused to adhere with solder to the connection land 501.

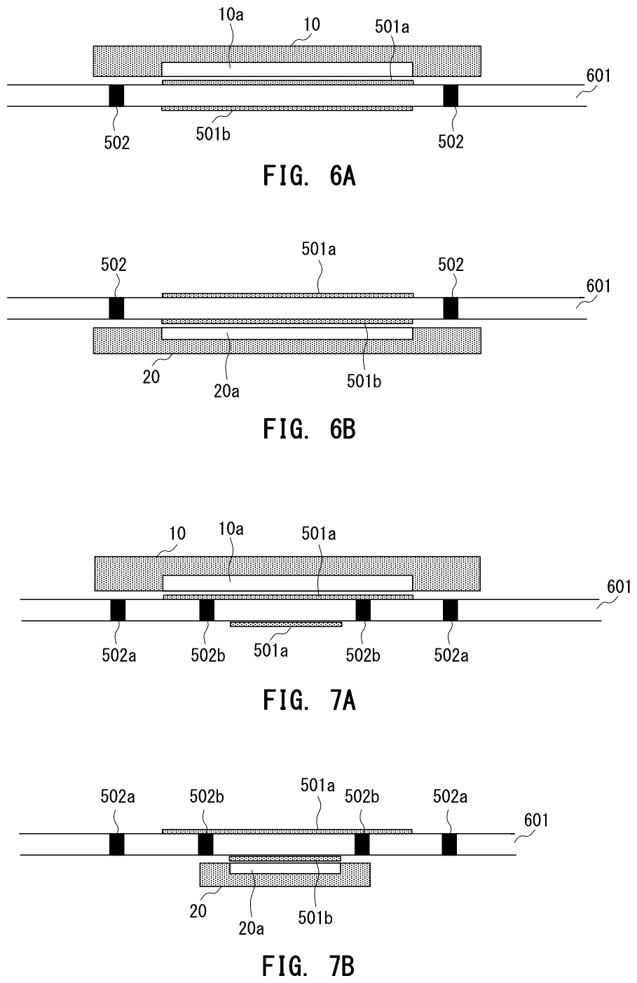

FIG. 6A and FIG. 6B are configuration diagrams of a circuit board in a case where the IC is mounted in a conventional way when the package size of the IC 10 and that of the IC 20 are the same. FIG. 6A and FIG. 6B are views obtained by viewing a circuit board 601 of the second voltage generation unit 303 from a lateral side. FIG. 6A shows a case in which the IC 10 is mounted. FIG. 6B shows a case in which the IC 20 is mounted.

A mounting region of the IC 10 and a mounting region of the IC 20 are arranged at positions opposite each other with the circuit board 601 in between. In the mounting region for the IC 10, a connection land 501a on which a heat dissipation surface 10a of the IC 10 is to be soldered is provided. In the mounting region for the IC 20, a connection land 501b on which a heat dissipation surface 20a of the IC 20 is to be soldered is provided. The through vias 502 are provided so that they penetrate through the circuit board 601 from a first side where the IC 10 is mounted to the second side where the IC 20 is mounted.

Depending on the procurement of the electronic parts, a first mounting pattern (FIG. 6A), in which the IC 10 is mounted on the first side, and a second mounting pattern (FIG. 6B), in which the IC 20 is mounted on the second side, are properly used. Since the IC 10 and the IC 20 have the same package size, a common arrangement of the through vias 502 can be used. Each of the mounting region of the IC 10 and the mounting region of the IC 20 is arranged at the same position when viewed from the upper side (first surface side) of the circuit board.

However, since the package sizes of the IC 10 and the IC 20 differ in many cases, it is necessary to provide the through vias for each IC. FIG. 7A and FIG. 7B are configuration diagrams of a circuit board in a case where the IC is mounted in a conventional way when the package size of the IC 10 and that of the IC 20 are different from each other. FIG. 7A and FIG. 7B are views obtained by viewing the circuit board 601 of the second voltage generation unit 303 from the lateral side. FIG. 7A shows a case in which the IC 10 is mounted. FIG. 7B shows a case in which the IC 20 is mounted. In the present embodiment, a description is made for a case where the package size of the IC 10 is larger than the package size of the IC 20.

The mounting region of the IC 10 and the mounting region of the IC 20 are arranged at positions opposite each other with the circuit board 601 in between. Since the IC 10 and the IC 20 have different package sizes, the areas (sizes) of the respective mounting regions are also different from each other. In the present embodiment, the mounting region of the IC 10 is wider than the mounting region of the IC 20. In the mounting region for the IC 10, the connection land 501a on which the heat dissipation surface 10a of the IC 10 is to be soldered is provided. In the mounting region for the IC 20, the connection land 501b on which the heat dissipation surface 20a of the IC 20 is to be soldered is provided. The through vias 502a are for the IC 10, and are provided so that they penetrate through the circuit board 601 from the first side where the IC 10 is mounted to the second side where the IC 20 is mounted. Through vias 502b are for the IC 20, and provided so that they penetrate through the circuit board 601 from the second side where the IC 20 is mounted to the first side where the IC 10 is mounted. The through vias 502b are provided in the area of the connection land 501a.

Depending on the procurement of the electronic parts, a first mounting pattern (FIG. 7A), in which the IC 10 is mounted on the first side, and a second mounting pattern (FIG. 7B), in which the IC 20 is mounted on the second side, are properly used. As illustrated in FIG. 7A, in a case where the IC 10 is to be implemented, the heat dissipation surface 10a of the IC 10 is soldered to the connection land 501a. At that time, solder for the connection land 501a may leak out to the second surface through the through vias 502b. As a result, the amount of solder between the IC 10 and the connection land 501a becomes insufficient. Due to the insufficient amount of solder, the IC 10 and the connection land 501a may become open state.

By providing a sufficient distance between the mounting region of the IC 10 and the mounting region of the IC 20 when viewed from the upper side (first surface side) of the circuit board, it is possible to prevent solder leakage from the through vias 502b. However, this increases the area of the circuit board 601. To reduce the size of the circuit board 601, it is preferable to shorten the distance between the mounting region of the IC 10 and the mounting region of the IC 20.

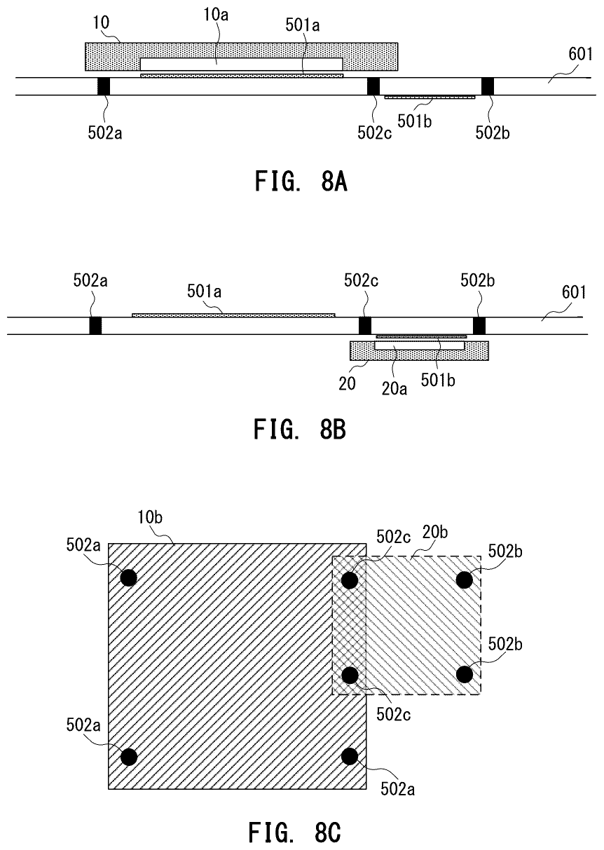

FIG. 8A, FIG. 8B, and FIG. 8C are exemplary views of configurations of the circuit board at the time when the IC is mounted in the present embodiment. The IC 10 and the IC 20 have different package sizes. FIG. 8A shows a case in which the IC 10 is mounted. FIG. 8B shows a case in which the IC 20 is mounted. FIG. 8A and FIG. 8B are views obtained by viewing the circuit board 601 of the second voltage generation unit 303 from the lateral side. FIG. 8C is a view obtained by viewing the circuit board 601 from the upper side (first surface side). A mounting region 10b for the IC 10 and the mounting region 20b for the IC 20 are provided so that they partially overlap each other as viewed from the upper side (in a direction perpendicular to a surface on which the mounting region is provided) of the mounting surface (first surface side). That is, a part including an outer edge of the mounting region 10b for the IC 10 overlaps the mounting region 20b for the IC 20, and another part of the mounting region 10b for the IC 10 is outside of the mounting region 20b for the IC 20. Further, a part including an outer edge of the mounting region 20b for the IC 20 overlaps the mounting region 10b for the IC 10, and another part of the mounting region 20b for the IC 20 is outside of the mounting region 10b for the IC 10.

The mounting region 10b of the IC 10 and the mounting region 20b of the IC 20 are arranged at positions opposite each other with the circuit board 601 in between. Since the IC 10 and the IC 20 have different package sizes, the areas (sizes) of the respective mounting regions 10b and 20b are also different from each other. In the present embodiment, the mounting region 10b of the IC 10 is wider than the mounting region 20b of the IC 20. In the mounting region 10b for the IC 10, the connection land 501a on which the heat dissipation surface 10a of the IC 10 is to be soldered is provided. In the mounting region for the IC 20, the connection land 501b on which the heat dissipation surface 20a of the IC 20 is to be soldered is provided. The through vias 502a are for the IC 10, and are provided so that they penetrate through the circuit board 601 from the first side where the IC 10 is mounted to the second side where the IC 20 is mounted. The through vias 502b are for the IC 20, and are provided so that they penetrate through the circuit board 601 from the second side where the IC 20 is mounted to the first side where the IC 10 is mounted. The through vias 502c are formed in a region in which the mounting region 10b for the IC 10 and the mounting region 20b for the IC 20 overlap each other so as to pass through the circuit board 601 from the first surface to the second surface. The through vias 502c are shared by the IC 10 and the IC 20 for heat dissipation, respectively.

The through vias 502a and 502c are formed for heat dissipation of the IC 10. The through vias 502b and 502c are formed for heat dissipation of the IC 20. With such a configuration, in a case where the IC 10 is mounted, the solder of the connection land 501a is prevented from leaking to the second surface through the through vias 502a, 502b, and 502c. Further, in a case where the IC 20 is mounted, the solder of the connection land 501b is prevented from leaking to the first surface through the through vias 502a, 502b, and 502c.

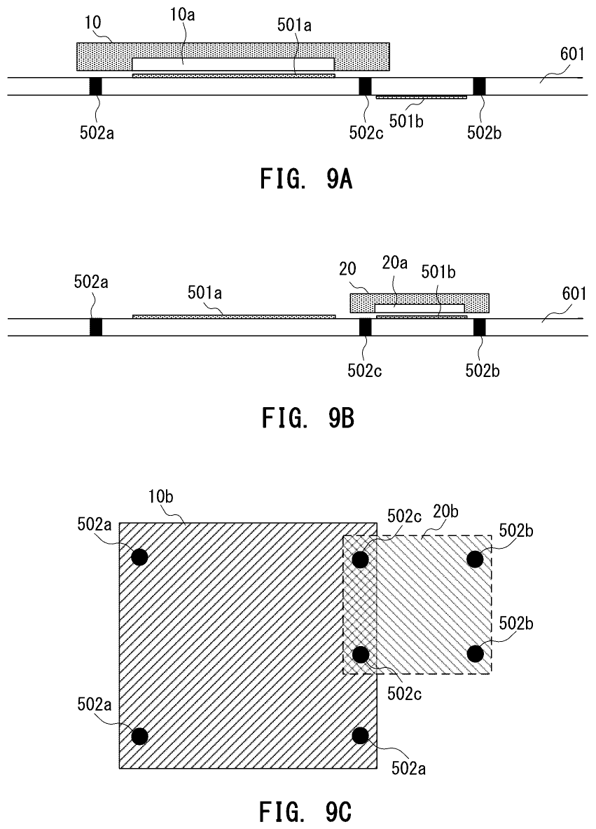

FIG. 9A, FIG. 9B, and FIG. 9C are exemplary views of other configurations of the circuit board at the time when the IC is mounted in the present embodiment. The IC 10 and the IC 20 have different package sizes. FIG. 9A shows a case in which the IC 10 is mounted. FIG. 9B shows a case in which the IC 20 is mounted. FIG. 9A and FIG. 9B are views obtained by viewing the circuit board 601 of the second voltage generation unit 303 from the lateral side. FIG. 9C is a view obtained by viewing the circuit board 601 from the upper side (first surface side). The mounting region 10b for the IC 10 and the mounting region 20b for the IC 20 are provided so that they partially overlap each other as viewed from the upper side (in a direction perpendicular to a surface on which the mounting region is provided) of the mounting surface. That is, a part including an outer edge of the mounting region 10b for the IC 10 overlaps the mounting region 20b for the IC 20, and another part of the mounting region 10b for the IC 10 is outside of the mounting region 20b for the IC 20. Further, a part including an outer edge of the mounting region 20b for the IC 20 overlaps the mounting region 10b for the IC 10, and another part of the mounting region 20b for the IC 20 is outside of the mounting region 10b for the IC 10.

The mounting region 10b of the IC 10 and the mounting region 20b of the IC 20 are arranged on the same surface of the circuit board 601. Since the IC 10 and the IC 20 have different package sizes, the areas (sizes) of the respective mounting regions 10b and 20b are also different from each other. In the present embodiment, the mounting region 10b of the IC 10 is wider than the mounting region 20b of the IC 20. In the mounting region 10b for the IC 10, the connection land 501a on which the heat dissipation surface 10a of the IC 10 is to be soldered is provided. In the mounting region for the IC 20, the connection land 501b on which the heat dissipation surface 20a of the IC 20 is to be soldered is provided. The configurations of the through vias 502a, 502b, and 502c are similar to that illustrated in FIGS. 8A, 8B, and 8C. With such a configuration, similar to the configuration illustrated in FIGS. 8A, 8B, and 8C, in a case where the IC 10 and the IC 20 are mounted, the solder is prevented from leaking through the through vias 502a, 502b, and 502c.

As described above, the electronic parts are exclusively mounted on the circuit board 601. With this configuration, while reducing the risk of parts unavailability that occurs in the procurement of an electronic part to be mounted, the circuit board 300 can be continuously manufactured even in a case where the electronic part lacks. Further, the mounting regions for the respective electronic parts are shifted from each other as viewed from the upper side of the circuit board, thereby being capable of preventing solder balls from being generated and partially sharing the through vias for heat dissipation. Accordingly, the solder is prevented from leaking through the through vias in a case where the electronic part is mounted, without losing the heat dissipation performance of the electronic part. Thus, the reduction in yield is suppressed. Moreover, a distance between the electronic parts can be set to a minimum distance that allows prevention of solder leakage, and hence an increase of the area of the circuit board 601 can be suppressed.

In the second embodiment, a description has been given of an example in which the IC 10 and the IC 20 of semiconductor devices are used as the electronic parts, however, the electronic parts are not limited thereto. The function of the electronic part is not limited as long as the electronic part is configured to be mounted with solder to the land on the circuit board 601. For example, the electronic part may be a switching IC, a Field Effect Transistor (FET), or the like.

Further, a description has been given of an example in which the IC 10 and the IC 20 are used as replacement parts. However, the effect to be obtained by the third embodiment is not limited to such an example. For example, in some cases, the circuit board 601 is designed as a common platform with respect to a plurality of apparatus. At this time, in one model, the first electronic part having a first function is mounted on the mounting region 10b, while, in another model, the second electronic part different from the first electronic part is mounted on the mounting region 20b. In such a case as well, the effect described in the third embodiment can be obtained. If a circuit board has a through via for heat dissipation or other purposes, solder may leak from the through via during soldering. Such leakage of the solder causes shortage of a solder amount between a heat dissipation plate and a heat transfer pattern. Shortage of the solder amount causes reduction in the heat dissipation property of the electronic part. Alternatively, there is a possibility that the leaking solder causes unintended electrical connection to hinder the circuit board from implementing a predetermined function. This results in reduction in yield of the circuit board. In contrast, as described above, according to the present disclosure, a circuit board that can suppress reduction in yield due to solder leakage through a through via can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-126985, filed Aug. 3, 2023, which is hereby incorporated by reference herein in its entirety.

What is claimed is:

1. A circuit board, comprising:
a first mounting region configured so that a first electronic part is mounted or mountable to the first mounting region;
a second mounting region configured so that a second electronic part is mounted or mountable to the second mounting region; and
a through via penetrating through the circuit board,
wherein the first mounting region includes a first part with an outer edge of the first mounting region and a second part,
wherein the second mounting region includes a third part with an outer edge of the second mounting region and a fourth part,
wherein, as viewed from a direction perpendicular to a surface on which the first mounting region is provided, the first part and the outer edge of the first mounting region overlap the second mounting region, and the second part of the first mounting region is positioned outside of the second mounting region,
wherein, as viewed from the direction, the third part and the outer edge of the second mounting region overlap the first mounting region, and the fourth part of the second mounting region is positioned outside of the first mounting region, and
wherein the through via is formed in a region where the first mounting region and the second mounting region overlap.

2. The circuit board according to claim 1,
wherein a first connection land to which the first electronic part is adhered is provided in the first mounting region, and
wherein a second connection land to which the second electronic part is adhered is provided in the first mounting region.

3. The circuit board according to claim 1, further comprising:
a first through via penetrating through the circuit board which is provided in the second part of the first mounting region, the first through via being positioned outside of the second mounting region as viewed from the direction; and
a second through via penetrating through the circuit board which is provided in the fourth part of the second mounting region, the second through via being positioned outside of the first mounting region as viewed from the direction.

4. The circuit board according to claim 2, wherein the first electronic part comprises a first heat dissipation surface, and the first heat dissipation surface is to be adhered to the first connection land.

5. The circuit board according to claim 4, wherein the first connection land and the first heat dissipation surface are adhered by soldering.

6. The circuit board according to claim 1,
wherein the first mounting region is provided at a first surface of the circuit board, and
wherein the second mounting region is provided at a second surface of the circuit board that is different from the first surface.

7. The circuit board according to claim 1, wherein the first mounting region and the second mounting region are provided on a same surface of the circuit board.

8. The circuit board according to claim 1, wherein the through via is configured to dissipate heat of the first electronic part or the second electronic part.

9. The circuit board according to claim 1,
wherein each of the first electronic part and the second electronic part is a semiconductor device,
wherein a first land for lead to which a lead of the first electronic part is connected is provided in the first mounting region, and
wherein a second land for lead to which a lead of the second electronic part is connected is provided in the second mounting region.

10. The circuit board according to claim 1, wherein an area of the first mounting region is different from an area of the second mounting region.

11. An image forming apparatus comprising:
the circuit board according to claim 1; and
a constituent part to be controlled by either one of the first electronic part or the second electronic part.
